(19) United States
(12) Patent Application Publication
(10) Pub. No.: US 2021/0320114 A1
(43) Pub. Date: Oct. 14, 2021

(54) SEMICONDUCTOR DEVICE AND MANUFACTURING METHOD THEREOF

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 16/998,733

(22) Filed: Aug. 20, 2020

(30) Foreign Application Priority Data
Apr. 10, 2020 (KR) 10-2020-0044168

(51) Int. Cl. H01L 27/11556; G11C 5/02; H01L 27/11582; H01L 23/00; H01L 23/538

(52) U.S. Cl. CPC H01L 27/11556; G11C 5/025; H01L 23/5386; H01L 24/06; H01L 27/11582

(57) ABSTRACT

A semiconductor device includes: a first semiconductor structure including a memory array; a second semiconductor structure spaced apart from the first semiconductor structure, the second semiconductor structure including a first transistor; a first insulating layer between the first semiconductor structure and the second semiconductor structure; a second insulating layer between the second semiconductor structure and the first insulating layer; a first bonding pad electrically connected to the memory array, the first bonding pad being located in the first insulating layer; and a second bonding pad electrically connected to the first transistor, the second bonding pad being located in the second insulating layer. The first bonding pad and the second bonding pad are in contact with each other. At least one sidewall of sidewalls of the first bonding pad and the second bonding pad includes a curved part.

### CROSS-REFERENCE TO RELATED APPLICATION

The present application claims priority under 35 U.S.C. § 119(a) to Korean patent application number 10-2020-0044168, filed on Apr. 10, 2020, in the Korean Intellectual Property Office, the entire disclosure of which is incorporated herein by reference.

### BACKGROUND

### 1. Technical Field

The present disclosure generally relates to an electronic device, and more particularly, to a semiconductor device and a manufacturing method thereof.

### 2. Related Art

A semiconductor device includes an integrated circuit configured with a Metal Oxide Semiconductor Field Effect Transistor (MOSFET). As the size and design rule of the semiconductor device are gradually reduced, scaling down of MOSFETs is gradually accelerated.

The scaling down of the MOSFETs may cause a short channel effect, etc., and therefore, operational characteristics of the semiconductor device may deteriorate. Accordingly, various methods have been researched for forming a semiconductor device having improved performance while overcoming a limitation due to high integration of the semiconductor device.

Further, such an integration circuit pursues operational reliability and low power consumption. Thus, a method for forming a device which has higher reliability and lower power consumption in a smaller form factor has been researched.

### SUMMARY

In accordance with an embodiment of the present disclosure, a semiconductor device includes: a first semiconductor structure including a memory array; a second semiconductor structure spaced apart from the first semiconductor structure, the second semiconductor structure including a first transistor; a first insulating layer between the first semiconductor structure and the second semiconductor structure; a second insulating layer between the second semiconductor structure and the first insulating layer; a first bonding pad electrically connected to the memory array, the first bonding pad being located in the first insulating layer; and a second bonding pad electrically connected to the first transistor, the second bonding pad being located in the second insulating layer, wherein the first bonding pad and the second bonding pad are in contact with each other, wherein at least one sidewall of sidewalls of the first bonding pad and the second bonding pad includes a curved part.

In accordance with another embodiment of the present disclosure, a semiconductor device includes: a first semiconductor structure including a stack structure, a channel structure penetrating the stack structure, and a bit line electrically connected to the channel structure; a second semiconductor structure spaced apart from the first semiconductor structure, the second semiconductor structure including a first transistor; a first insulating layer between the first semiconductor structure and the second semiconductor structure; a second insulating layer between the second semiconductor structure and the first insulating layer; a first bonding pad located in the first insulating layer, the first bonding pad being electrically connected to the channel structure; and a second bonding pad located in the second insulating layer, the second bonding pad being electrically connected to the first transistor, the second bonding pad being in contact with the first bonding pad, wherein the first bonding pad includes: a first part in contact with the second bonding pad; a second part in contact with the bit line; and a third part between the first part and the second part, wherein a sidewall of the third part is curved.

In accordance with still another embodiment of the present disclosure, a method of manufacturing a semiconductor device includes: forming an insulating layer; forming a hard mask layer including a first opening on the Insulating layer; forming a second opening in the insulating layer by etching the insulating layer, using the hard mask layer as an etch barrier; expanding the first opening of the hard mask layer; forming a third opening and a fourth opening in the insulating layer by etching the insulating layer, using the hard mask layer as an etch barrier, after the first opening is expanded; and forming a bonding pad in the third opening and the fourth opening, wherein a width of the fourth opening is greater than a width of the third opening, wherein the third opening and the fourth opening overlap with each other, wherein a corner between the third opening and the fourth opening of the insulating layer is curved.

In accordance with still another embodiment of the present disclosure, a method of manufacturing a semiconductor device includes: forming an Insulating layer; forming a hard mask layer including a first opening on the insulating layer; forming a second opening by etching the insulating layer, using the hard mask layer as an etch barrier; exposing a top surface of the insulating layer by expanding the first opening of the hard mask layer; forming a third opening and a fourth opening in the insulating layer by etching the insulating layer, using the hard mask layer as an etch barrier, after expanding the first opening; and forming a bonding pad in the third opening and the fourth opening, wherein a width of the fourth opening is greater than a width of the third opening, wherein the third opening and the fourth opening overlap with each other.

### BRIEF DESCRIPTION OF THE DRAWINGS

Example embodiments are described hereinafter with reference to the accompanying drawings; however, they may be embodied in different forms and should not be construed as being limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1A is a plan view of a semiconductor device in accordance with an embodiment of the present disclosure.

FIG. 1B is a sectional view taken along line A-A′ shown in FIG. 1A.

FIGS. 2A to 2F are sectional views illustrating a manufacturing method of the semiconductor device shown in FIGS. 1A and 1B.

FIG. 3 is a sectional view of a semiconductor device in accordance with an embodiment of the present disclosure.

FIG. 4 is a sectional view of a semiconductor device in accordance with an embodiment of the present disclosure.

FIG. 5A is a sectional view of a semiconductor device in accordance with an embodiment of the present disclosure.

FIG. 5B is a plan view of a second bonding structure of a first region, which is viewed along line B-B′ shown in FIG. 5A.

FIG. 5C is a plan view of a second bonding structure of a second region, which is viewed along the line B-B′ shown in FIG. 5A.

FIG. 6 is a sectional view of a semiconductor device in accordance with an embodiment of the present disclosure.

FIGS. 7A to 7H are sectional views illustrating a manufacturing method of the semiconductor device shown in FIGS. 5A to 5C.

FIG. 8 is a block diagram illustrating a configuration of a memory system in accordance with an embodiment of the present disclosure.

FIG. 9 is a block diagram illustrating a configuration of a computing system in accordance with an embodiment of the present disclosure.

### DETAILED DESCRIPTION

The specific structural and functional descriptions disclosed herein are merely illustrative for the purpose of describing embodiments according to the concept of the present disclosure. The embodiments according to the concept of the present disclosure can be implemented in various forms, and should not be construed as being limited to the embodiments set forth herein.

Some embodiments are directed to a semiconductor device capable of improving operational reliability and a manufacturing method of the semiconductor device.

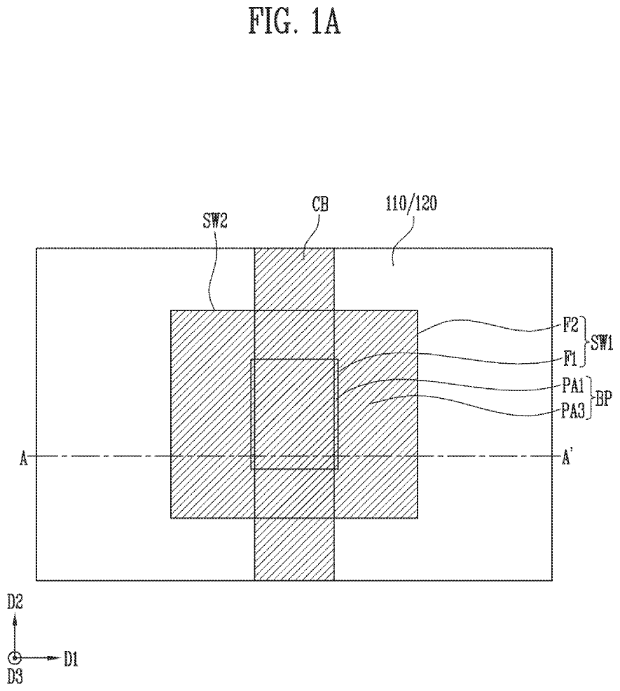

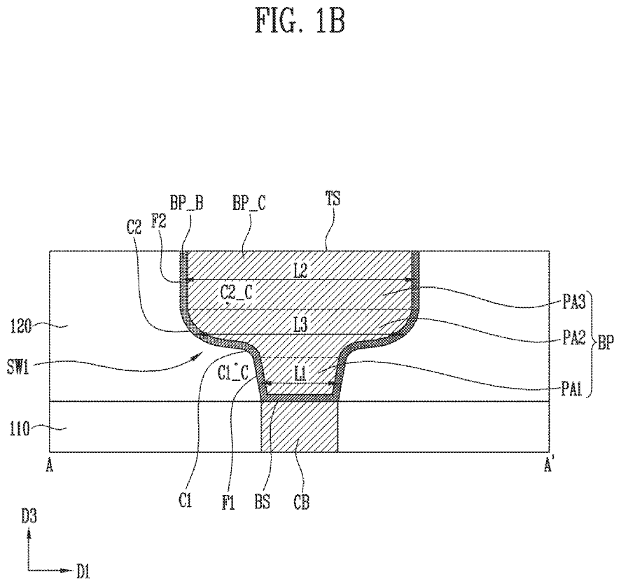

FIG. 1A is a plan view of a semiconductor device in accordance with an embodiment of the present disclosure. FIG. 1B is a sectional view taken along line A-A′ shown in FIG. 1A.

Referring to FIGS. 1A and 1B, the semiconductor device may include a first insulating layer 110, a second insulating layer 120, a conductor CB, and a bonding pad BP.

The first insulating layer 110 may have the shape of a plate expanding along a plane defined by a first direction D1 and a second direction D2. The first direction D1 and the second direction D2 may be different intersecting directions. In an example, the first direction D1 and the second direction D2 may be orthogonal to each other. The first insulating layer 110 may include an insulating material. In an example, the first insulating layer 110 may include oxide or nitride.

The conductor CB may be provided in the first insulating layer 110. The conductor CB may extend in the second direction D2. A top surface of the conductor CB may be located on the same plane as a top surface of the first insulating layer 110. The conductor CB may include a conductive material. In an example, the conductor CB may include copper, aluminum, or tungsten.

The second insulating layer 120 may be provided on the first insulating layer 110. The second insulating layer 120 may have the shape of a plate expanding along a plane defined by the first direction D1 and the second direction D2. The second insulating layer 120 may include an insulating material. In an example, the second insulating layer 120 may include SiCN.

The bonding pad BP may be provided in the second insulating layer 120. The bonding pad PB may penetrate the second insulating layer 120 in a third direction D3. The third direction D3 may intersect the first direction D1 and the second direction D2. In an example, the third direction D3 may be orthogonal to the first direction D1 and the second direction D2.

The bonding pad BP may include a conductive part BP_C and a barrier part BP_B. The barrier part BP_B may be provided on a surface of the second insulating layer 120. The conductive part BP_C may be provided on a surface of the barrier part BP_B. The barrier part BP_B may be provided between the conductive part BP_C and the second insulating layer 120. The conductive part BP_C and the second insulating layer 120 may be spaced apart from each other by the barrier part BP_B.

The conductive part BP_C may include a conductive material. In an example, the conductive part BP_C may include copper, aluminum, or tungsten. In an example, the barrier part BP_B may include titanium, titanium nitride, tantalum, or tantalum nitride.

The bonding pad BP may include first sidewalls SW1 facing each other in the first direction D1 and second sidewalls SW2 facing each other in the second direction D2. The first sidewalls SW1 and the second sidewalls SW2 may be connected to each other. The second sidewalls SW2 may connect the first sidewalls SW1 to each other. The first sidewall SW1 may connect the second sidewalls SW2 to each other. The first and second sidewalls SW1 and SW2 of the bonding pad BP may be defined by the surface of the barrier part BP_B.

Each of the first sidewalls SW1 of the bonding pad BP may include a first flat part F1, a second flat part F2, a first curved part C1, and a second curved part C2. The first flat part F1 may be connected to the first curved part C1. The first curved part C1 may be connected to the second curved part C2. The second flat part F2 may be connected to the second curved part C2. The first flat part F1, the first curved part C1, the second curved part C2, and the second flat part F2 are connected, to constitute the first sidewall SW1 of the bonding pad BP.

The first flat part F1 may be connected to a bottom surface BS of the bonding pad BP. The second flat part F2 may be connected to a top surface TS of the bonding pad BP. From the sectional viewpoint shown in FIG. 1B, the first flat part F1 and the second flat part F2 may be represented as straight lines. In an example, from the sectional viewpoint shown in FIG. 1B, a first curvature center C1_C of the first curved part C1 may be located at the outside of the bonding pad BP. In an example, from the sectional viewpoint shown in FIG. 1B, a second curvature center C2_C of the second curved part C2 may be located at the inside of the bonding pad BP.

The first curved part C1 and the second curved part C2 may be curved in different directions. In an example, the first curved part C1 may be curved such that a central portion of the first curved part C1 protrudes (is convex) toward the inside of the bonding pad BP, and the second curved part C2 may be curved such that a central portion of the second curved part C2 protrudes (is convex) toward the outside of the bonding pad BP.

A distance between the first flat parts F1 in the first direction D1 may be defined as a first distance L1. The first distance L1 may decrease as the first flat parts F1 come closer to the conductor CB. A distance between the second flat parts F2 in the first direction D1 may be defined as a second distance L2. The second distance L2 may decrease as the second flat parts F2 come closer to the conductor CB. Alternatively, the second distance L2 may be constant at all levels. The second distance L2 may be greater than the first distance L1.

A distance between the first curved parts C1 in the first direction D1 and a distance between the second curved parts C2 in the first direction D1 may be defined as a third distance L3. The third distance L3 may decrease as the first curved parts C1 and the second curved parts C2 come closer to the conductor CB. A maximum value of the third distance L3 may be equal to a minimum value of the second distance L2. A minimum value of the third distance L3 may be equal to a maximum value of the first distance L1.

The bonding pad BP may include a first part PA1, a second part PA2, and a third part PA3. The first part PA1 may be a portion connected to the conductor CB. The second part PA2 may be a portion connected to the first part PAL. The third part PA3 may be a portion connected to the second part PA2. The second part PA2 may be provided between the first part PA1 and the third part PA3.

A sidewall of the first part PA1 may be defined by the first flat part F1. The sidewall of the first part PA1 may be flat. A sidewall of the second part PA2 may be defined by the first and second curved parts C1 and C2. The sidewall of the second part PA2 may be curved. The first curved part C1 may be formed at a portion of the sidewall of the second part PA2, which is connected to the first part PA1. The second curved part C2 may be formed at a portion of the sidewall of the second part PA2, which is connected to the third part PA3. A sidewall of the third part PA3 may be defined by the second flat part F2. The sidewall of the third part PA3 may be flat.

A width of the first part PA1 may decrease as the first part PA1 comes closer to the conductor CB. In an example, the width of the first part PA1 in the first direction D1 may decrease as the first part PA1 comes closer to the conductor CB. The width of the first part PA1 in the first direction D1 may be equal to the first distance L1.

A width of the second part PA2 may decrease as the second part PA2 comes closer to the conductor CB. In an example, the width of the second part PA2 in the first direction D1 may decrease as the second part PA2 comes closer to the conductor CB. The width of the second part PA2 in the first direction D1 may be equal to the third distance L3.

A width of the third part PA3 may decrease as the third part PA3 comes closer to the conductor CB. In an example, the width of the third part PA3 in the first direction D1 may decrease as the third part PA3 comes closer to the conductor CB. The width of the third part PA3 in the first direction D1 may be equal to the second distance L2.

Similarly to the first sidewalls SW1, each of the second sidewalls SW2 of the bonding pad BP may include curved parts and flat parts.

In the semiconductor device in accordance with this embodiment, the sidewalls of the bonding pads BP include curved parts, and the width of the third part PA3 as an upper portion of the bonding pad BP is relatively large. Hence, the bonding pad BP can have an improved gap fill characteristic, and the bonding pad BP can be formed without any void. Further, because the width of the first part PA1 as a lower portion of the bonding pad BP is relatively small, an overlay margin between the conductor CB and the bonding pad BP can be secured.

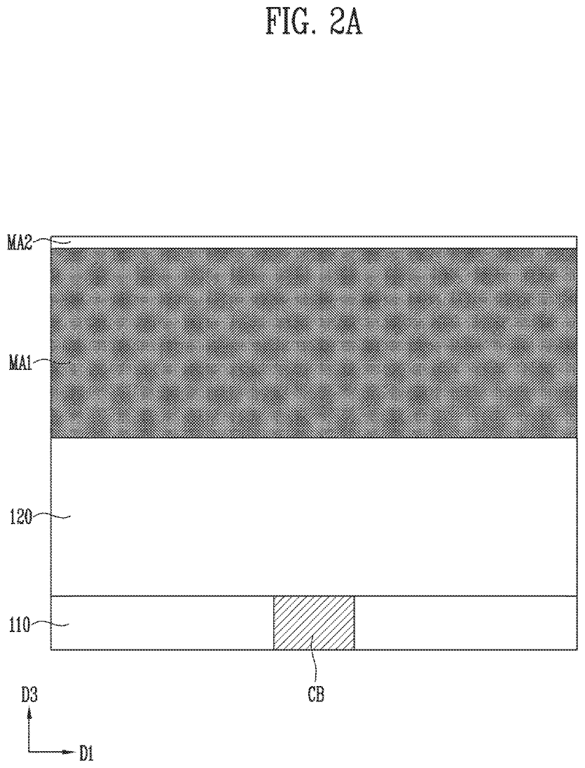

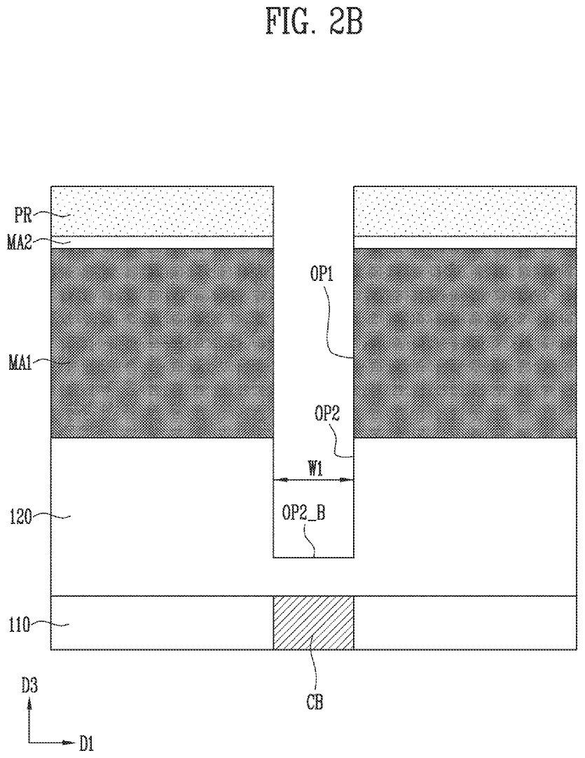

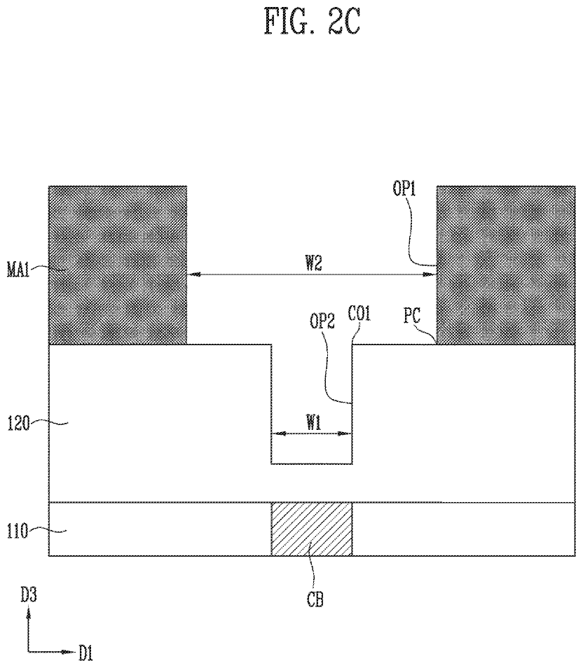

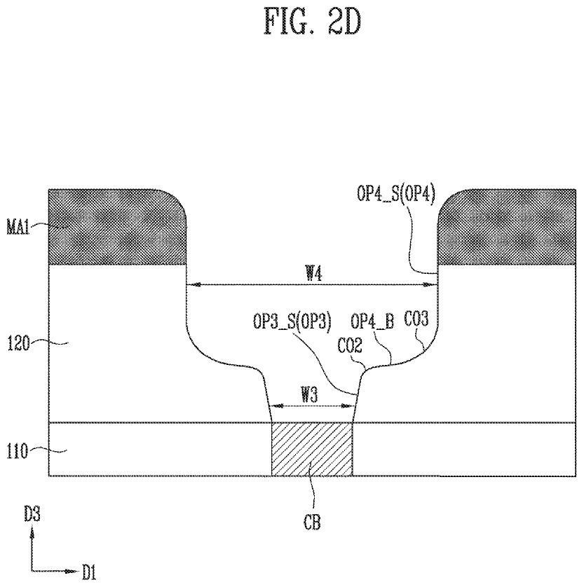

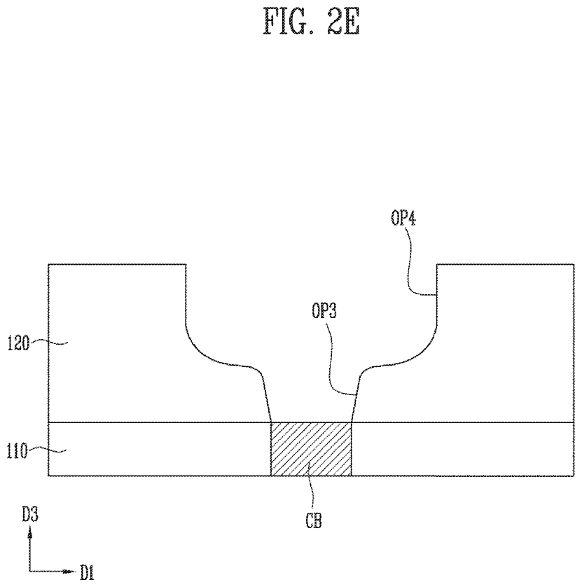

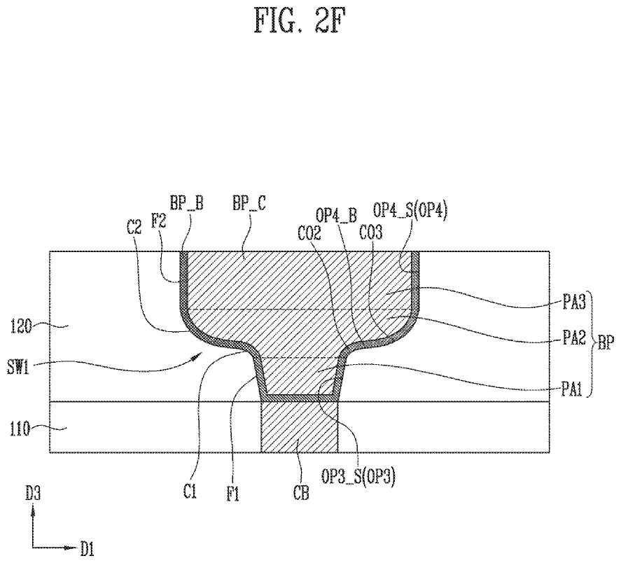

FIGS. 2A to 2F are sectional views illustrating a manufacturing method of the semiconductor device shown in FIGS. 1A and 1B. For brevity, redundant descriptions of components already described with reference to FIGS. 1A and 1B will be omitted.

The manufacturing method described below is merely an embodiment of a method of manufacturing the semiconductor memory device shown in FIGS. 1A and 1B, and methods of manufacturing the semiconductor memory device shown in FIGS. 1A and 1B are not limited to the manufacturing method described below.

Referring to FIG. 2A, a conductor CB may be formed in a first insulating layer 110. A trench may be formed by etching the first insulating layer 110, and the conductor CB may be formed in the trench. The conductor CB may be an interconnection structure. In an example, the conductor CB may be a bit line, a contact plug, or a line.

The first insulating layer 110 may include an insulating material. In an example, the first insulating layer 110 may include oxide or nitride. The conductor CB may include a conductive material. In an example, the conductor CB may include copper, aluminum, or tungsten.

A second insulating layer 120 may be formed on the first insulating layer 110. The second insulating layer 120 may include an insulating material. In an example, the second insulating layer 120 may include SiCN. In an example, the second insulating layer 120 may be a single layer.

A first hard mask layer MA1 may be formed on the second insulating layer 120. A thickness of the first hard mask layer MA1 may be greater than that of the second insulating layer 120. A length of the first hard mask layer MA1 in the third direction D3 may be greater than that of the second insulating layer 120 in the third direction D3. In an example, the first hard mask layer MA1 may include amorphous carbon.

A second hard mask layer MA2 may be formed on the first hard mask layer MA1. The second hard mask layer MA2 may include an insulating material. In an example, the second hard mask layer MA2 may include SiON.

Referring to FIG. 2B, a photoresist pattern PR may be formed on the second hard mask layer MA2. After a photoresist layer is formed on the second hard mask layer MA2, the photoresist pattern PR may be formed by patterning the photoresist layer through an exposure and development process.

Subsequently, the second hard mask layer MA2 and the first hard mask layer MA1 may be etched by using the photoresist pattern PR as an etch barrier. Accordingly, the first and second hard mask layers MA1 and MA2 may be patterned, and a first opening OP1 may be formed in the first hard mask layer MA1.

Subsequently, the second insulating layer 120 may be etched by using the first hard mask layer MA1 as an etch barrier. Accordingly, the second insulating layer 120 may be patterned, and a second opening OP2 may be formed in the second insulating layer 120.

The second opening OP2 may be formed such that the conductor CB is not exposed. The second opening OP2 may penetrate a portion of the second insulating layer 120. The second opening OP2 might not completely penetrate the second insulating layer 120.

A bottom surface OP2_B of the second opening OP2 may be defined by the second insulating layer 120. A level of the bottom surface OP2_B of the second opening OP2 may be higher than that of a bottom surface of the second insulating layer 120. The bottom surface OP2_B of the second opening OP2 may be spaced apart from the conductor CB in the third direction D3. A portion of the second insulating layer 120 may be provided between the bottom surface OP2_B of the second opening OP2 and the conductor CB.

A width of the second opening OP2 in the first direction D1 may be defined as a first width W1. The first width W1 may be substantially equal to that of the conductor CB in the first direction D1. A width of the first opening OP1 may be substantially equal to that of the second opening OP2. A width of the first opening OP1 in the first direction D1 may be equal to the first width W1.

In an embodiment, as shown in the drawing, the photoresist pattern PR and the second hard mask layer MA2, which remain after the first opening OP1 and the second opening OP2 are formed, may be removed. In another embodiment, unlike as shown in the drawing, the second opening OP2 may be formed after the first opening OP1 is formed and the photoresist pattern PR and the second hard mask layer MA2 are removed. The second hard mask layer MA2 may protect the first hard mask layer MA1 while the photoresist pattern PR is being removed. When the photoresist pattern PR and the second hard mask layer MA2 are removed after the first opening OP1 is formed, a top surface of the first hard mask layer MA1 may be exposed in the process of forming the second opening OP2, and a portion of the top surface of the first hard mask layer MA1 may be etched.

Referring to FIG. 2C, the first opening OP1 of the first hard mask layer MA1 may be expanded. By etching the first hard mask layer MA1, the first hard mask layer MA1 may be reduced, and the first opening OP1 may be expanded. In an example, the first hard mask layer MA1 may be etched by using an isotropic etching process. According to the etching process, a length (height) of the first hard mask layer MA1 in the third direction D3 may decrease, and the width of the first opening OP1 may increase. In an example, the width of the first opening OP1 in the first direction D1 may increase to a second width W2. The second width W2 may be greater than the first width W1. When the first opening OP1 is expanded, a top surface of the second insulating layer 120 may be exposed. When the first opening OP1 is expanded, a first corner CO1 between the top surface of the second insulating layer 120 and a sidewall of the second opening OP2 may be exposed. When the first opening OP1 is expanded, a first contact point PC between the top surface of the second insulating layer 120 and a sidewall of the first hard mask layer MA1 may be defined. The first contact point PC may be a contact point between the top surface of the second insulating layer 120 and a sidewall of the expanded first opening OP1.

Referring to FIG. 2D, the second insulating layer 120 may be etched by using the first hard mask layer MA1 as an etch barrier. The second insulating layer 120 may be etched through the first opening OP1.

The second insulating layer 120 may be etched while the first opening OP1 and the second opening OP2 are being transferred downward. While the second opening OP2 is being transferred, a third opening OP3 may be formed in the second insulating layer 120. The third opening OP3 may be formed to expose the conductor CB. While the first opening OP1 is being transferred, a fourth opening OP4 may be formed in the second insulating layer 120. The third opening OP3 and the fourth opening OP4 may overlap with each other. In an example, the third opening OP3 and the fourth opening OP4 may vertically overlap with each other.

A width of the third opening OP3 in the first direction D1 may be defined as a third width W3. A width of the fourth opening OP4 in the first direction D1 may be defined as a fourth width W4. The fourth width W4 may be greater than the third opening W3. When the third opening OP3 and the fourth opening OP4 are formed, a T-shaped opening may be formed in the second insulating layer 120. A sidewall OP3_S of the third opening OP3 may be flat. A sidewall OP4_S of the fourth opening OP4 may be flat.

While the second insulating layer 120 is being etched, a second corner CO2 and a third corner CO3 may be formed in the second insulating layer 120. The second and third corners CO2 and CO3 may be defined by the third and fourth openings OP3 and OP4. The second corner CO2 may be formed at a portion at which the third opening OP3 and the fourth opening OP4 are connected to each other, and the third corner CO3 may be formed at a portion at which a bottom surface OP4_B and a sidewall OP4_S of the fourth opening OP4 are connected to each other.

The second corner CO2 of the second insulating layer 120 may be formed when the first corner (CO1 shown in FIG. 2C) is transferred downward, and be located corresponding to the first corner (CO1 shown in FIG. 2C). The third corner CO3 of the second insulating layer 120 may be formed when the first contact point (PC shown in FIG. 2C) is transferred downward, and be located corresponding to the first contact point (PC shown in FIG. 2C).

In the etching process, because the first corner (CO1 shown in FIG. 2C) relatively protrudes, the first corner (CO1 shown in FIG. 2C) may be relatively highly exposed to an etching environment, and an etching amount of the first corner (CO1 shown in FIG. 2C) may be relatively large. Accordingly, the first corner (CO1 shown in FIG. 2C) may be transferred downward while being rounded, and the curved second corner CO2 may be formed.

In the etching process, the first contact point (PC shown in FIG. 2C) may be relatively low exposed to an etching environment, and an etching amount of the first contact point (PC shown in FIG. 2C) may be relatively small. Accordingly, the first contact point (PC shown in FIG. 2C) may be transferred downward while being rounded, and the curved third corner CO3 may be formed.

The bottom surface OP4_B of the fourth opening OP4 may be connected between the second corner CO2 and the third corner CO3 of the second insulating layer 120. The bottom surface OP4_B of the fourth opening OP4 may be flat or curved. The second corner CO2 may be formed between the bottom surface OP4_B of the fourth opening OP4 and the sidewall OP3_S of the third opening OP3. The third corner CO3 may be formed between the bottom surface OP4_B of the fourth opening OP4 and the sidewall OP4_S of the fourth opening OP4.

A curvature center of the second corner CO2 may be located in the second insulating layer 120. A curvature center of the third corner CO3 may be located in the fourth opening OP4.

Referring to FIG. 2E, the first hard mask layer MA1 may be removed. In an example, the first hard mask layer MA1 may be removed through a cleaning process.

Referring to FIG. 2F, a bonding pad BP may be formed in the second insulating layer 120. A first part PA1 of the bonding pad BP may be formed in the third opening OP3. A second part PA2 and a third part PA3 of the bonding pad BP may be formed in the fourth opening OP4.

The bonding pad BP may include a conductive part BP_C and a barrier part BP_B.

A first sidewall SW1 of the bonding pad BP may include a first flat part F1, a second flat part F2, a first curved part C1, and a second curved part C2. A sidewall of the first part PA1 of the bonding pad BP may be flat while being in contact with the sidewall OP3_S of the third opening OP3 of the second insulating layer 120. A sidewall of the second part PA2 of the bonding pad BP may be curved while being in contact with the second and third corners CO2 and CO3 of the second insulating layer 120 and the bottom surface OP4_B of the fourth opening OP4. A sidewall of the third part PA3 of the bonding pad BP may be flat while being in contact with the sidewall OP4_S of the fourth opening OP4 of the second insulating layer 120.

When the bonding pad BP is formed in the second insulating layer 120, a width of the third part PA3 as an upper portion of the bonding pad BP in the first direction D1 may be greater than that of the first part PA1 as a lower portion of the bonding pad BP.

Because the width of the fourth opening OP4 of the second insulating layer 120 is relatively large, the bonding pad BP can be formed without any void. Because the width of the third opening OP3 of the second insulating layer 120 is relatively small, an overlay margin between the bonding pad BP and the conductor CB can be secured.

In the manufacturing method of the semiconductor device in accordance with this embodiment, after the second opening OP2 in the second insulating layer 120 and the first opening OP1 in the first hard mask layer MA1 are formed, the first opening OP1 is expanded. Subsequently, the second insulating layer 120 is etched through the expanded first opening OP1. Accordingly, the third opening OP3 and the fourth opening OP4, which have different widths, are formed in the second insulating layer 120 as a single layer.

The third opening OP3 and the fourth opening OP4 are formed through a one-time etching process, so that the cost and time of the etching process can be reduced, and the curved second and third corners CO2 and CO3 can be formed in the second insulating layer 120. The bonding pad BP is formed in the second insulating layer 120 in which the curved second and third corners CO2 and C03 are formed, so that a gap fill characteristic of the bonding pad BP can be improved, and the bonding pad BP can be formed without any void.

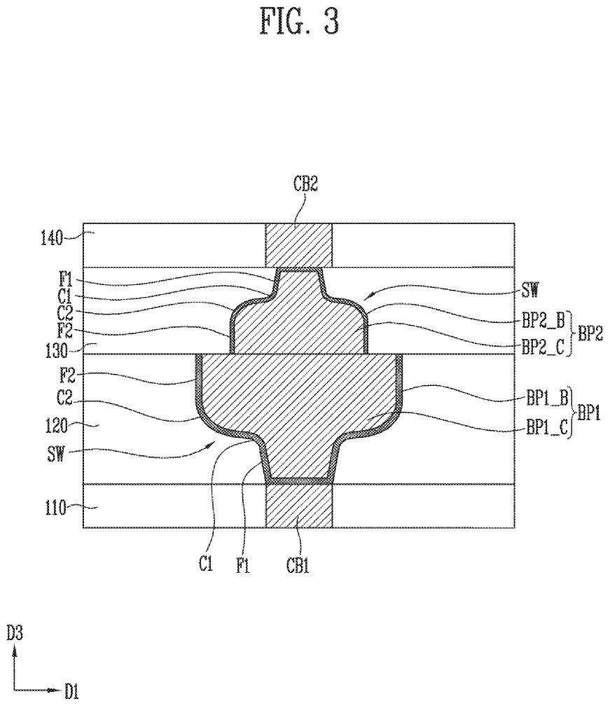

FIG. 3 is a sectional view of a semiconductor device in accordance with an embodiment of the present disclosure.

The semiconductor device in accordance with this embodiment may be similar to the semiconductor device shown in FIGS. 1A and 1B, except portions described below.

Referring to FIG. 3, the semiconductor device in accordance with this embodiment may include a first insulating layer 110, a second insulating layer 120, a third insulating layer 130, and a fourth insulating layer 140.

A first conductor CB1 may be provided in the first insulating layer 110, a first bonding pad BP1 may be provided in the second insulating layer 120, a second bonding pad BP2 may be provided in the third insulating layer 130, and a second conductor CB2 may be provided in the fourth insulating layer 140.

The first conductor CB1 may be connected to the first bonding pad BP1, the first bonding pad BP1 may be connected to the second bonding pad BP2, and the second bonding pad BP2 may be connected to the second conductor CB2. The first and second conductors CB1 and CB2 may be electrically connected to each other by the first and second bonding pads BP1 and BP2.

The first bonding pad BP1 may include a conductive part BP1_C and a barrier part BP1_B. The second bonding pad BP2 may include a conductive part BP2_C and a barrier part BP2_B. A sidewall of each of the first bonding pad BP1 and the second boding pad BP2 may include a first flat part F1, a second flat part F2, a first curved part C1, and a second curved part C2.

The first flat part F1 of each of the first bonding pad BP1 and the second bonding pad BP2 may be connected to the first conductor CB1 or the second conductor CB2. The second flat part F2 of the first bonding pad BP1 may be connected to the third insulating layer 130. The second flat part F2 of the second bonding pad BP2 may be connected to the first bonding pad BP1.

A portion of a top surface of the first bonding pad BP1 may be in contact with a bottom surface of the second bonding pad BP2. Another portion of the top surface of the first bonding pad BP1 may be in contact with a portion of a bottom surface of the third insulating layer 130. A width of the top surface of the first bonding pad BP1 in the first direction D1 may be greater than that of the bottom surface of the second bonding pad BP2 in the first direction D1.

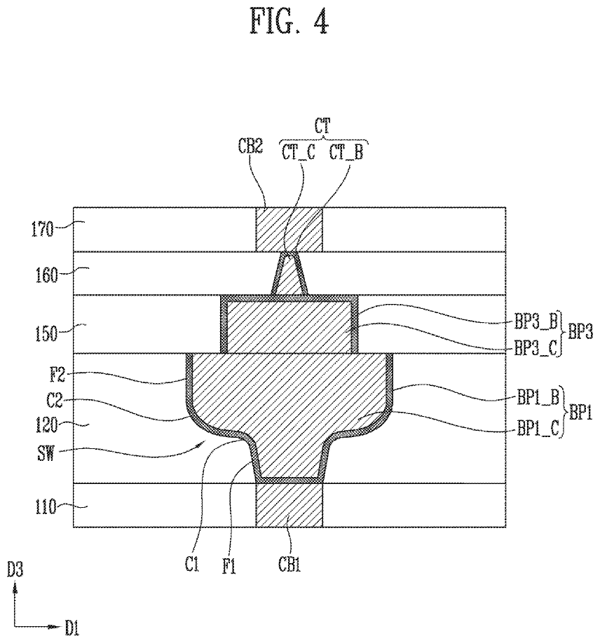

FIG. 4 is a sectional view of a semiconductor device in accordance with an embodiment of the present disclosure.

The semiconductor device in accordance with this embodiment may be similar to the semiconductor device shown in FIG. 3, except portions described below.

Referring to FIG. 4, the semiconductor device in accordance with this embodiment may include a first insulating layer 110, a second insulating layer 120, a fifth insulating layer 150, a sixth insulating layer 160, and a seventh insulating layer 170.

A first conductor CB1 may be provided in the first insulating layer 110, a first bonding pad BP1 may be provided in the second insulating layer 120, a third bonding pad BP3 may be provided in the fifth insulating layer 150, a contact CT may be provided in the sixth insulating layer 160, and a second conductor CB2 may be provided in the seventh insulating layer 170.

The first conductor CB1 may be connected to the first bonding pad BP1, the first bonding pad BP1 may be connected to the third bonding pad BP3, the third bonding pad BP3 may be connected to the contact CT, and the contact CT may be connected to the second conductor CB2. The first and second conductors CB1 and CB2 may be electrically connected to each other by the contact CT, the third bonding pad BP3, and the first bonding pad BP1.

The first bonding pad BP1 may include a conductive part BP1_C and a barrier part BP1_B. The third bonding pad BP3 may include a conductive part BP3_C and a barrier part BP3_B. The contact CT may include a conductive part CT_C and a barrier part CT_B.

A sidewall SW of the first bonding pad BP1 may include a first flat part F1, a second flat part F2, a first curved part C1, and a second curved part C2. A sidewall of the third bonding pad BP3 may be flat. A sidewall of the contact CT may be flat.

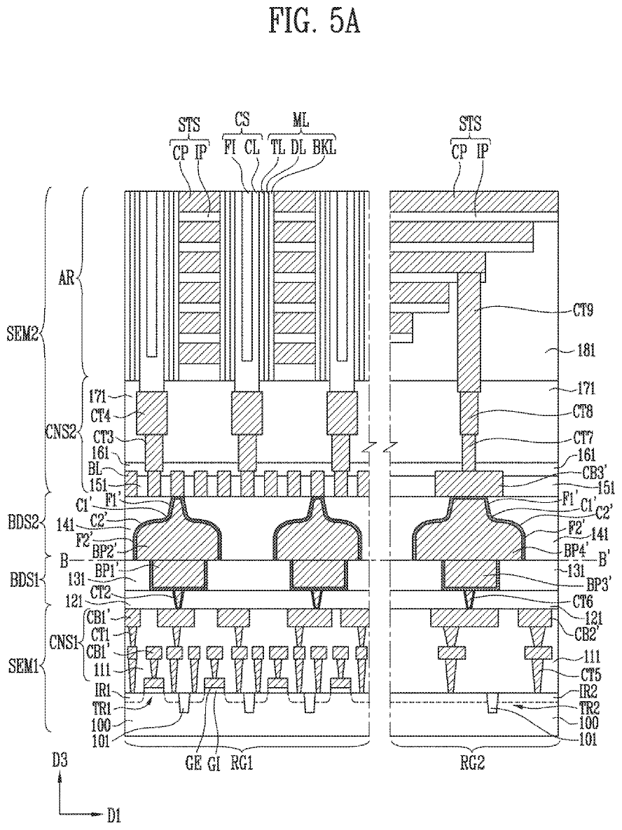

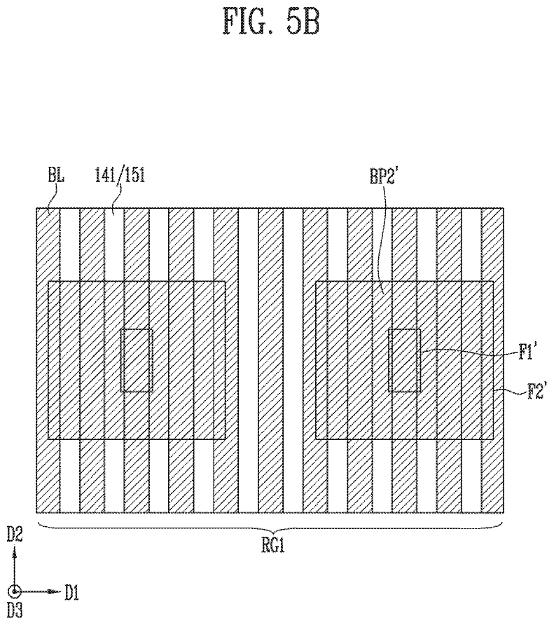

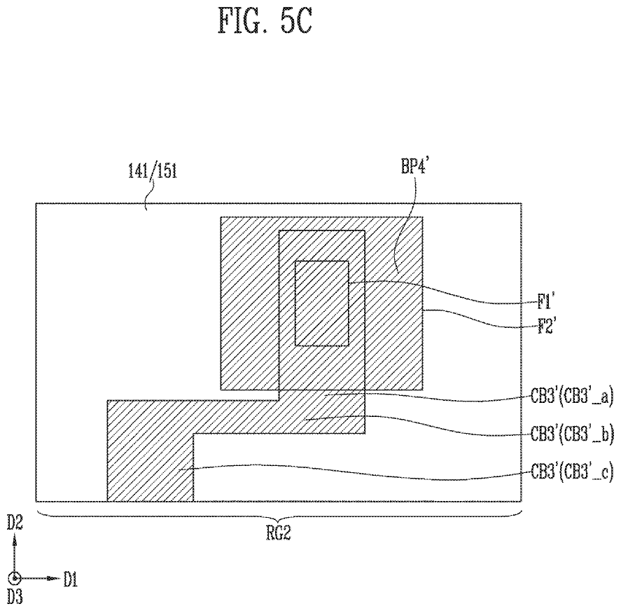

FIG. 5A is a sectional view of a semiconductor device in accordance with an embodiment of the present disclosure. FIG. 5B is a plan view of a second bonding structure of a first region, which is viewed along line B-B′ shown in FIG. 5A. FIG. 5C is a plan view of a second bonding structure of a second region, which is viewed along the line B-B′ shown in FIG. 5A.

Referring to FIG. 5A, the semiconductor device in accordance with this embodiment may include a first semiconductor structure SEM1, a second semiconductor structure SEM2, a first bonding structure BDS1, and a second bonding structure BDS2.

The first and second semiconductor structures SEM1 and SEM2 may be spaced apart from each other. The first semiconductor structure SEM1 and the first bonding structure BDS1 may be connected to each other, the first and second bonding structures BDS1 and BDS2 may be connected to each other, and the second bonding structure BDS2 and the second semiconductor structure SEM2 may be connected to each other. The first semiconductor structure SEM1 and the second semiconductor structure SEM2 may be electrically connected to each other by the first and second bonding structures BDS1 and BDS2.

The semiconductor device may include a first region RG1 and a second region RG2. Each of the first semiconductor structure SEM1, the second semiconductor structure SEM2, the first bonding structure BDS1, and the second bonding structure BDS2 may be divided into the first region RG1 and the second region RG2.

The first semiconductor structure SEM1 may include a substrate 100, first and second transistors TR1 and TR2 in the substrate 100, and a first connection structure CNS1.

The first transistors TR1 may be provided in the substrate 100 of the first region RG1. In an example, the first transistors TR1 may be transistors constituting a page buffer. In an example, the substrate 100 may be a semiconductor substrate.

Each first transistor TR1 may include first impurity regions IR1 and a first gate structure. In an example, the first impurity region IR1 may be formed by doping the substrate 100 with an impurity. In an example, the first gate structure may include a gate electrode GE and a gate insulating layer GI between the gate electrode GE and the substrate 100.

An isolation layer 101 may be provided in the substrate 100 of the first region RG1. The isolation layer 101 may electrically isolate the first transistors TR1 from each other. The isolation layer 101 may include an insulating material.

The first connection structure CNS1 may include a first insulating layer 111, first contacts CT1, and first conductors CB1′. The first insulating layer 111 may be formed on the substrate 100. The first contacts CT1 and the first conductors CB1′ may be provided in the first insulating layer 111 of the first region RG1.

The first insulating layer 111 may include an insulating material. The first contacts CT1 and the first conductors CB1′ may include a conductive material.

The first contacts CT1 and the first conductors CB1′ may be electrically connected to the first transistor TR1 in the first substrate 100.

The first bonding structure BDS1 may include a second insulating layer 121, a third insulating layer 131, second contacts CT2, and first bonding pads BP1′. The second insulating layer 121 may be formed on the first insulating layer 111, and the third insulating layer 131 may be formed on the second insulating layer 121.

The second contacts CT2 may be provided in the second insulating layer 121 of the first region RG1. The first bonding pads BP1′ may be provided in the third insulating layer 131 of the first region RG1. Each of the second contacts CT2 and the first bonding pads BP1′ may include a conductive part and a barrier part. A sidewall of each of the second contacts CT2 and the first bonding pads BP1′ may be flat.

The second and third insulating layers 121 and 131 may include an insulating material. The second contacts CT2 and the first bonding pads BP1′ may include a conductive material. The second contact CT2 may be connected to the first conductor CB1′, and the first bonding pad BP1′ may be connected to the second contact CT2.

The second bonding structure BDS2 may include a fourth insulating layer 141 and second bonding pads BP2′. The fourth insulating layer 141 may be formed on the third insulating layer 131.

The second bonding pads BP2′ may be provided in the fourth insulating layer 141 of the first region RG1. Each of the second bonding pads BP2′ may include a conductive part and a barrier part. A sidewall of the second bonding pad BP2′ may include a first flat part F1′, a second flat part F2′, a first curved part C1′, and a second curved part C2′. The first and second curved parts C1′ and C2′ may be provided between the first and second flat parts F1′ and F2′.

The fourth insulating layer 141 may include an insulating layer. In an example, the fourth insulating layer 141 may include SiCN. The second bonding pads BP2′ may include a conductive material. The second bonding pad BP2′ may be connected to the first bonding pad BP1′.

The second semiconductor structure SEM2 may include a memory array AR and a second connection structure CNS2.

The second connection structure CNS2 may include a fifth insulating layer 151, a sixth insulating layer 161, a seventh insulating layer 171, bit lines BL, third contacts CT3, and fourth contacts CT4.

The fifth insulating layer 151 may be formed on the fourth insulating layer 141, the sixth insulating layer 161 may be formed on the fifth insulating layer 151, and the seventh insulating layer 171 may be formed on the sixth insulating layer 161.

The bit lines BL may be provided in the fifth insulating layer 151 and the sixth insulating layer 161 of the first region RG1. The third contacts CT3 may be provide in the sixth insulating layer 161 and the seventh insulating layer 171 of the first region RG1. The fourth contacts CT4 may be provided in the seventh insulating layer 171 of the first region RG1.

The fifth to seventh insulating layers 151, 161, and 171 may include an insulating material. In an example, the fifth and seventh insulating layers 151 and 171 may include oxide. In an example, the sixth insulating layer 161 may include nitride. The third and fourth contacts CT3 and CT4 may include a conductive material. The bit lines BL may include a conductive material.

The bit line BL may be connected to the second bonding pad BP2′, the third contact CT3 may be connected to the bit line BL, and the fourth contact CT4 may be connected to the third contact CT3.

A width of the bit line BL may be equal to that of a bottom surface of the second bonding pad BP2′. In an example, a width of the bit line BL in the first direction D1 may be equal to that of the bottom surface of the second bonding pad BP2′ in the first direction D1.

Referring to FIG. 5B, the bit lines BL may extend in the second direction D2. The bit lines BL may be spaced apart from each other in the first direction D1. The second bonding pad BP2′ may overlap with a plurality of bit lines BL.

Referring back to FIG. 5A, the memory array AR may be provided on the second connection structure CNS2. The memory array AR may include a stack structure STA, channel structures CS, and memory layers ML.

The stack structure STS may be provided on the seventh insulating layer 171. The stack structure STS may include conductive patterns CP and insulating patterns IP, which are alternately stacked. The conductive patterns CP may include a conductive material. In an example, the conductive patterns CP may include at least one of a doped silicon layer, a metal silicide layer, tungsten, nickel, and cobalt. The insulating patterns IP may include an insulating material. In an example, the insulating patterns IP may include oxide.

The channel structures CS and the memory layers ML may penetrate the stack structure STS. The channel structure CS may include a filling layer FI and a channel layer CL surrounding the filling layer FI. The memory layer ML may include a tunnel Insulating layer TL surrounding the channel structure CS, a data storage layer DL surrounding the tunnel insulating layer TL, and a blocking layer BKL surrounding the data storage layer DL.

The filling layer FI may include an insulating material. In an example, the filling layer FI may include oxide. The channel layer CL may include a semiconductor material. In an example, the channel layer CL may include poly-silicon. The tunnel insulating layer TL may include a material through which charges can tunnel. In an example, the tunnel insulating layer TL may include oxide. In an example, the data storage layer DL may include nitride in which charges can be trapped. However, the material which the data storage layer DL includes is not limited to the nitride, and may be variously changed depending on a data storage method. In example, the data storage layer DL may include silicon, a phase change material, or nano dots. The blocking layer BKL may include a material capable of blocking movement of charges. In an example, the blocking layer BKL may include oxide.

The channel structure CS may be connected to the fourth contact CT4. The channel structure CS may be electrically connected to the first transistor TR in the substrate 100 through the fourth contact CT4, the third contact CT3, the bit line BL, the second bonding pad BP2′, the first boding pad BP1′, the second contact CT2, the first conductor CB1′, and the first contact CT1.

The memory array AR may be electrically connected to the fourth contact CT4, the third contact CT3, the bit line BL, the second bonding pad BP2′, the first bonding pad BP1′, the second contact CT2, the first conductor CB1′ and the first contact CT1, to be electrically connected to the first transistor TR1 in the substrate 100.

The second transistors TR2 may be provided in the substrate 100 of the second region RG2. In an example, the second transistors TR2 may be pass transistors connected to an X-decoder.

Each second transistor TR2 may include second impurity regions IR2 and a second gate structure. In an example, the second impurity region IR2 may be formed by doping the substrate 100 with an impurity. In an example, similarly to the first gate structure, the second gate structure may include a gate electrode and a gate insulating layer between the gate electrode and the substrate 100.

An isolation layer 101 may be provided in the substrate 100 of the second region RG2. The isolation layer 101 may electrically isolate the second transistors TR2 from each other.

Fifth contacts CT5 and second conductors CB2′ may be provided in the first insulating layer 111 of the second region RG2. The fifth contact CT5 may be connected to the second transistor TR2. The second conductor CB2′ may be connected to the fifth contact CT5.

A sixth contact CT6 may be provided in the second insulating layer 121 of the second region RG2. A third bonding pad BP3′ may be provided in the third insulating layer 131 of the second region RG2. Each of the sixth contact CT6 and the third bonding pad BP3′ may include a conductive part and a barrier part. The sixth contact CT6 and the third bonding pad BP3′ may include a conductive material.

The sixth contact CT6 may be connected to the second conductor CB2′. The third bonding pad BP3′ may be connected to the sixth contact CT6. A sidewall of each of the sixth contact CT6 and the third bonding pad BP3′ may be flat.

A fourth bonding pad BP4′ may be provided in the fourth insulating layer 141 of the second region RG2. The fourth bonding pad BP4′ may include a conductive part and a barrier part. A sidewall of the fourth bonding pad BP4′ may include a first flat part F1′, a second flat part F2′, a first curved part C1′ and a second curved part C2′. The first and second curved parts C1′ and C2′ may be provided between the first and second flat parts F1′ and F2′.

The fourth bonding pad BP4′ may include a conductive material. The fourth bonding pad BP4′ may be connected to the third bonding pad BP3′.

A third conductor CB3′ may be provided in the fifth insulating layer 151 and the sixth insulating layer 161 of the second region RG2. A sixth contact CT7 may be provided in the sixth insulating layer 161 and the seventh insulating layer 171 of the second region RG2. An eighth contact CT8 may be provided in the seventh insulating layer 171 of the second region RG2.

Referring to FIG. 5C, the third conductor CB3′ may include first to third parts CB3′_a, CB3′_b, and CB3′_c. The first and third parts CB3′_a and CB3′_c may extend in the second direction D2. The second part CB3′_b may extend in the first direction D1 and connect the first and third parts CB3′_a and CB3′_c. The first part CB3′_a may be connected to the fourth bonding pad BP4′. The fourth bonding pad BP4′ may overlap with the first part CB3′_a of the third conductor CB3′.

Referring back to FIG. 5A, the third conductor CB3′, the seventh contact CT7, and the eighth contact CT8 may include a conductive material. The third conductor CB3′ may be connected to the fourth bonding pad BP4′, the seventh contact CT7 may be connected to the third conductor CB3′, and the eighth contact CT8 may be connected to the seventh contact CT7.

An eighth insulating layer 181 may be provided on the seventh insulating layer 171 of the second region RG2. A stack structure STS may be provided on the on the eighth insulating layer 181. The eighth insulating layer 181 may include an insulating material.

The stack structure STS of the second region RG2 may have a stepped structure. Insulating patterns IP and conductive patterns CP of the stack structure STS of the second region RG2 are formed in the shape of steps, so that the stepped structure can be formed.

A ninth contact CT9 may be provided in the seventh insulating layer 171 and the eighth insulating layer 181. The ninth contact CT9 may be connected to the eighth contact CT8. The ninth contact CT9 may be connected to the conductive pattern CP of the stack structure STS. The ninth contact CT9 may include a conductive material.

The conductive pattern CP may be electrically connected to the second transistor TR2 through the ninth contact CT9, the eighth contact CT8, the seventh contact CT7, the third conductor CB3′, the fourth bonding pad BP4′, the third bonding pad BP3′, the sixth contact CT6, the second conductor CB2′, and the fifth contact CT5.

In the semiconductor device in accordance with this embodiment, because the width of a portion connected to the bit line BL of the second bonding pad BP2′ is relatively small, an overlay margin between the bit line BL and the second bonding pad BP2′ can be secured.

In the semiconductor device in accordance with this embodiment, because the width of a portion connected to the third conductor CB3′ of the fourth bonding pad BP4′ is relatively small, an overlay margin between the third conductor CB3′ and the fourth bonding pad BP4′ can be secured.

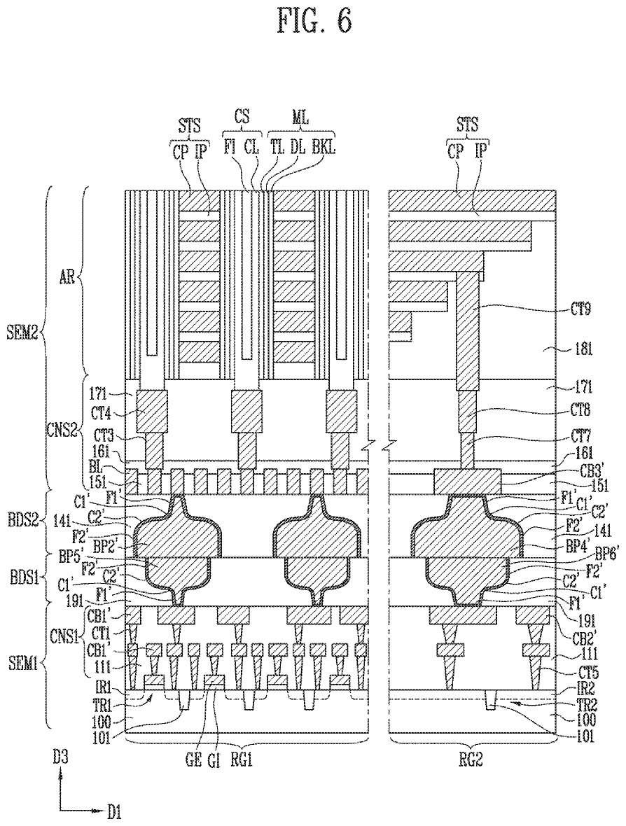

FIG. 6 is a sectional view of a semiconductor device in accordance with an embodiment of the present disclosure.

The semiconductor device in accordance with this embodiment may be similar to the semiconductor device shown in FIGS. 5A to 5C, except portions described below.

Referring to FIG. 6, in the semiconductor device in accordance with this embodiment, the first bonding structure BDS1 may include a ninth insulating layer 191. The ninth insulating layer 191 may be provided between the first insulating layer 111 and the fourth insulating layer 141.

Fifth bonding pads BP5′ may be provided in the ninth insulating layer 191 of the first region RG1. A sidewall of the fifth bonding pad BP5′ may include a first flat part F1′, a second flat part F2′, a first curved part C1′, and a second curved part C2′. The fifth bonding pad BP5′ may be connected to the second bonding pad BP2′ of the second bonding structure BDS2.

A sidewall of the second bonding pad BP2′ may include a first flat part F1′, a second flat part F2, a first curved part C1′ and a second curved part C2′.

A sixth bonding pad BP6′ may be provided in the ninth insulating layer 191 of the second region RG2. A sidewall of the sixth bonding pad BP6′ may include a first flat part F1′, a second flat part F2′, a first curved part C1′, and a second curved part C2′. The sixth bonding pad BP6′ may be connected to the fourth bonding pad BP4′ of the second bonding structure BDS2.

A sidewall of the fourth bonding pad BP4′ may include a first flat part F1′, a second flat part F2, a first curved part C1, and a second curved part C2′.

The fifth bonding pad BP5′ may be connected to a first transistor TR1 through the first conductor CB1′ and the first contact CT1 of the first connection structure CNS1. In an example, the first transistor TR1 may be a transistor constituting a page buffer.

The sixth bonding pad BP6′ may be connected to a second transistor TR2 through the second conductor CB2′ and the fifth contact CT5 of the first connection structure CNS1. In an example, the second transistor TR2 may be a pass transistor connected to an X-decoder.

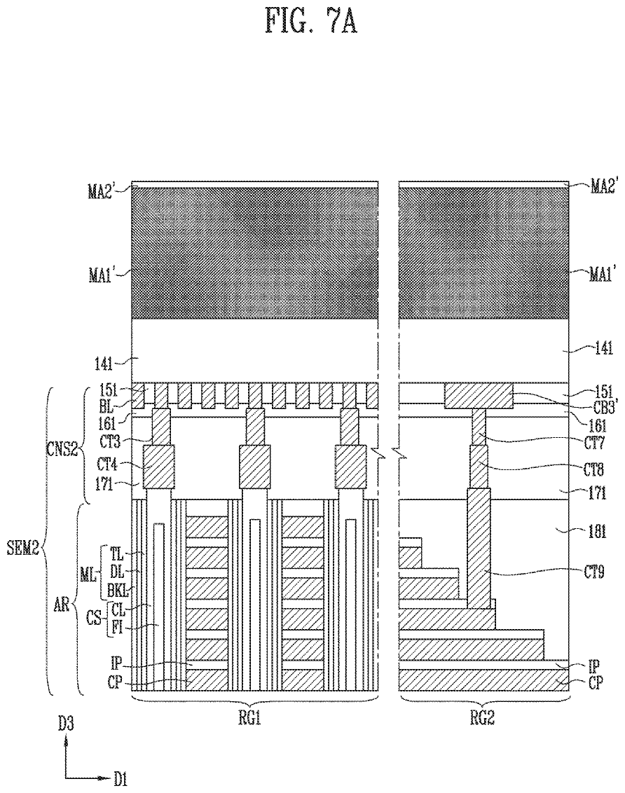

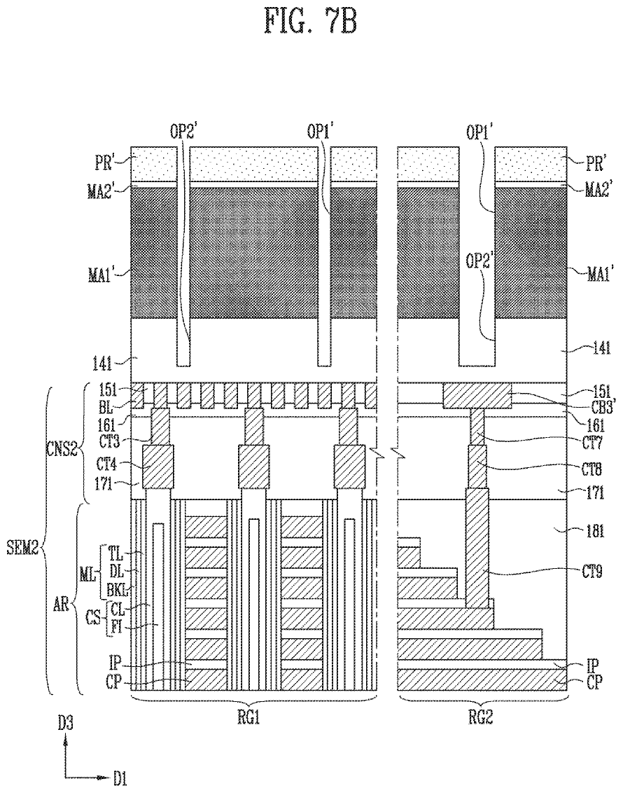

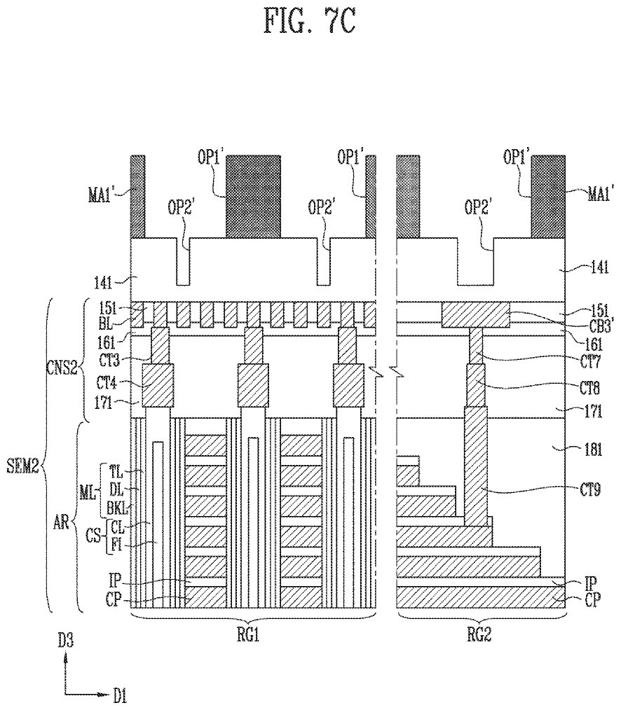

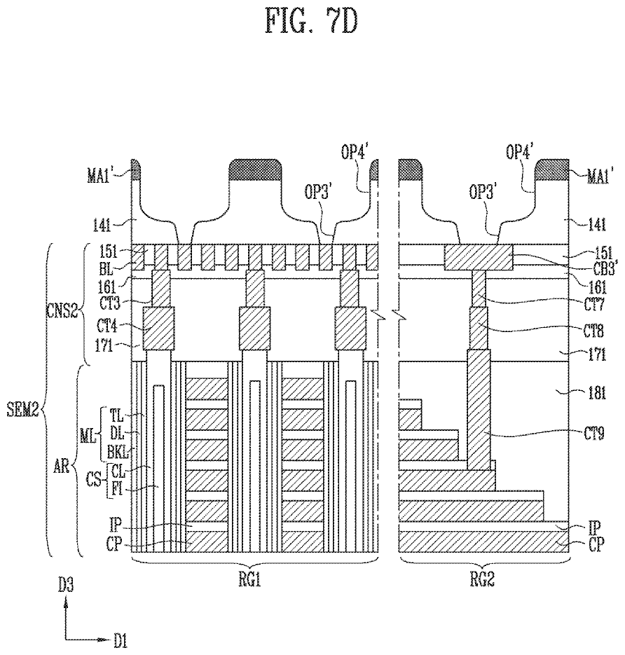

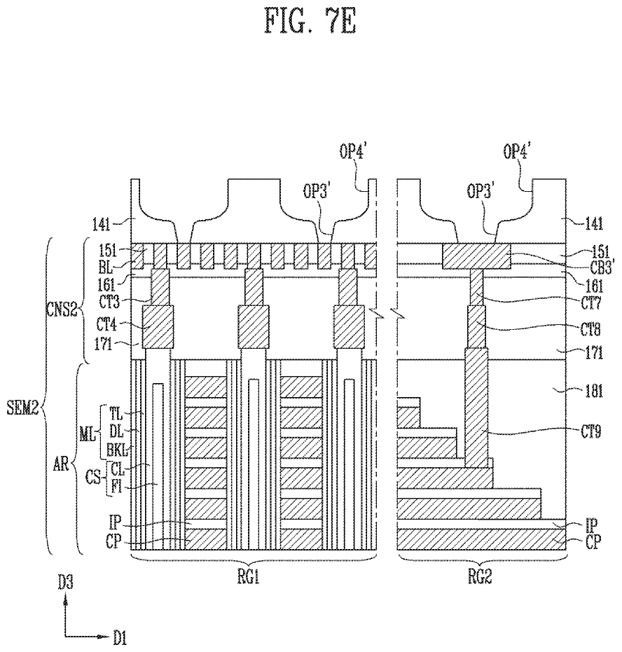

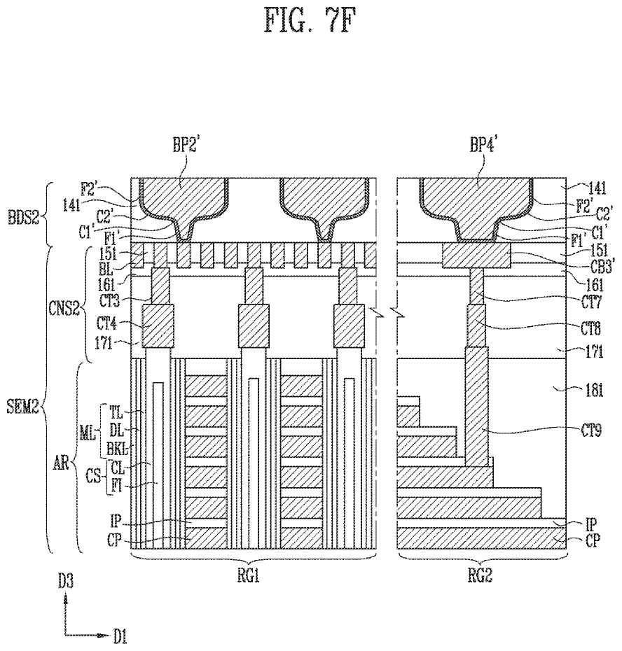

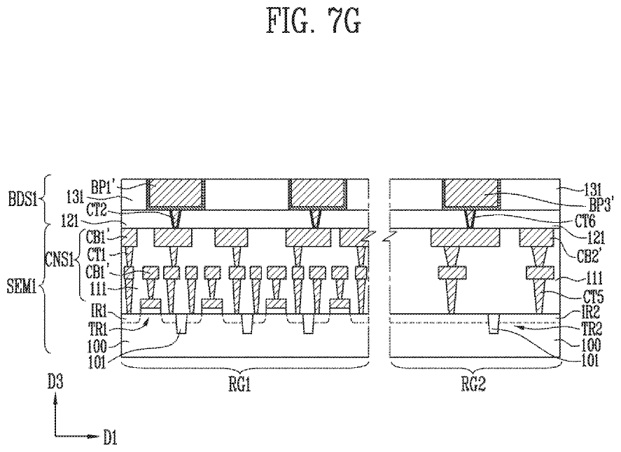

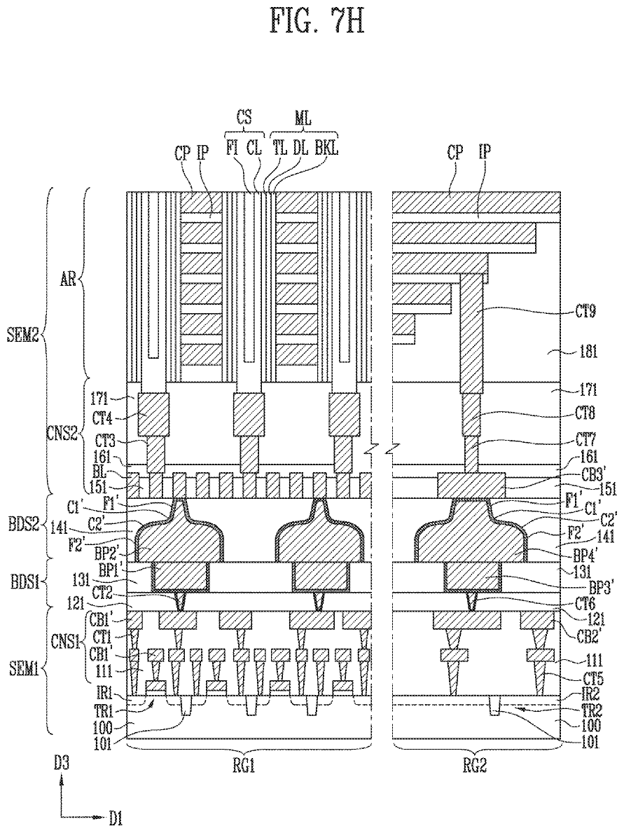

FIGS. 7A to 7H are sectional views illustrating a manufacturing method of the semiconductor device shown in FIGS. 5A to 5C.

For brevity, redundant descriptions of components already described with reference to FIGS. 5A to 5C will be omitted.

The manufacturing method described below is merely an embodiment of a method of manufacturing the semiconductor memory device shown in FIGS. 5A to 5C, and methods of manufacturing the semiconductor memory device shown in FIGS. 5A to 5C are not limited to the manufacturing method described below.

Referring to FIG. 7A, a second semiconductor structure SEM2 may be formed. The second semiconductor structure SEM2 may include a memory array AR and a second connection structure CNS2.

A fourth insulating layer 141 may be formed on the second connection structure CNS2, a first hard mask layer MA1′ may be formed on the fourth insulating layer 141, a second hard mask layer MA2′ may be formed on the first hard mask layer MA1′. In an example, the fourth insulating layer 141 may be a single layer.

Referring to FIG. 7B, a photoresist pattern PR′ may be formed on the second hard mask layer MA2′.

Subsequently, the second hard mask layer MA2′ and the first hard mask layer MA1′ may be etched by using the photoresist pattern PR′ as an etch barrier. Accordingly, the first and second hard mask layers MA1′ and MA2′ may be patterned, and a first opening OP1′ may be formed in the first hard mask layer MA1′.

Subsequently, the fourth insulating layer 141 may be etched by using the first hard mask layer MA1′ as an etch barrier. Accordingly, the fourth insulating layer 141 may be patterned, and a second opening OP2′ may be formed in the fourth insulating layer 141.

In an embodiment, as shown in the drawing, the photoresist pattern PR′ and the second hard mask layer MA2, which remain after the first opening OP1′ and the second opening OP2′ are formed, may be removed. In another embodiment, unlike as shown in the drawing, the second opening OP2′ may be formed after the first opening OP1′ is formed and the photoresist pattern PR′ and the second hard mask layer MA2′ are removed.

Referring to FIG. 7C, the first opening OP1′ of the first hard mask layer MA1′ may be expanded. By etching the first hard mask layer MA1′, the first hard mask layer MA1′ may be reduced, and the first opening OP1′ may be expanded. When the first opening OP1′ is expanded, a top surface of the fourth insulating layer 141 may be exposed.

Referring to FIG. 7D, the fourth insulating layer 141 may be etched by using the first hard mask layer MA1′ as an etch barrier. The fourth insulating layer 141 may be etched through the first opening (OP1′ shown in FIG. 7C).

When the fourth insulating layer 141 is etched, the first opening (OP1′ shown in FIG. 7C) and the second opening (OP2′ shown in FIG. 7C) may be transferred in the fourth insulating layer 141. When the second opening (OP2′ shown in FIG. 7C) is transferred, a third opening OP3′ may be formed in the fourth insulating layer 141. When the first opening (OP1′ shown in FIG. 7C) is transferred, a fourth opening OP4′ may be formed in the fourth insulating layer 141.

The third opening OP3′ of a first region RG1 may be formed to expose a bit line BL. The third opening OP3′ of a second region RG2 may be formed to expose a third conductor CB3′ electrically connected to a conductive pattern CP of a stack structure STS.

A sidewall of the third opening OP3′ and a sidewall of the fourth opening OP4′ may be flat. A surface of the fourth insulating layer 141, which connects the third opening OP3′ and the fourth opening OP4′, may be curved. When the fourth insulating layer 141 is etched, a curved sidewall may be formed in the fourth insulating layer 141.

Referring to FIG. 7E, the first hard mask layer MA1′ may be removed.

Referring to FIG. 7F, a second bonding pad BP2′ may be formed in the fourth insulating layer 141 of the first region RG1. The second bonding pad BP2′ may include a first flat part F1′, a second flat part F2′, a first curved part C1′, and a second curved part C2′. The second bonding pad BP2′ may be connected to the bit line BL.

A fourth bonding pad BP4′ may be formed in the fourth insulating layer 141 of the second region RG2. The fourth bonding pad BP4′ may include a first flat part F1′, a second flat part F2′, a first curved part C1′, and a second curved part C2′. The fourth bonding pad BP4′ may be connected to the third conductor CB3′ electrically connected to the conductive pattern CP of the stack structure STS. When the second bonding pattern BP2′ and the fourth bonding pattern BP4′ are formed, a second bonding structure BDS2 may be formed.

Referring to FIG. 7G, a first semiconductor structure SEM1 and a first bonding structure BDS1 may be formed. The first semiconductor structure SEM1 may include a substrate 100, first and second transistors TR1 and TR2 in the substrate 100, and a first connection structure CNS1.

The first bonding structure BDS1 may include second and third insulating layers 121 and 131. A first bonding pad BP1′ may be provided in the third insulating layer 131 of the first region RG1. A third bonding pad BP3′ may be provided in the third insulating layer 131 of the second region RG2. Sidewalls of the first and third bonding pads BP1′ and BP3′ may be flat.

Referring to FIG. 7H, the first bonding structure BDS1 and the second bonding structure BDS2 may be bonded to each other. After the second semiconductor structure SEM2 and the second bonding structure BDS2 are rotated, the first bonding structure BDS1 and the second bonding structure BDS2 may be bonded to each other. In an example, the second semiconductor structure SEM2 and the second bonding structure BDS2 may be rotated by 180 degrees.

When the first bonding structure BDS1 and the second bonding structure BDS2 are bonded to each other, the first semiconductor structure SEM1 and the second semiconductor structure SEM2 may be electrically connected to each other.

The first bonding pad BP1′ of the first bonding structure BDS1 and the second bonding pad BP2′ of the second bonding structure BDS2 may be bonded to each other. When the first bonding pad BP1′ of the first bonding structure BDS1 and the second bonding pad BP2′ of the second bonding structure BDS2 are bonded to each other, a channel structure CS may be electrically connected to the first transistor TR1. In an example, the channel structure CS may be connected to a transistor constituting a page buffer. When the first bonding pad BP1′ of the first bonding structure BDS1 and the second bonding pad BP2′ of the second bonding structure BDS2 are bonded to each other, the memory array AR may be electrically connected to the first transistor TR1.

The third bonding pad BP3′ of the first bonding structure BDS1 and the fourth bonding pad BP4′ of the second bonding structure BDS2 may be bonded to each other. When the third bonding pad BP3′ of the first bonding structure BDS1 and the fourth bonding pad BP4′ of the second bonding structure BDS2 are bonded to each other, the conductive pattern CP of the stack structure STS may be electrically connected to the second transistor TR2. In an example, the conductive pattern CP of the stack structure STS may be connected to a pass transistor connected to an X-decoder.

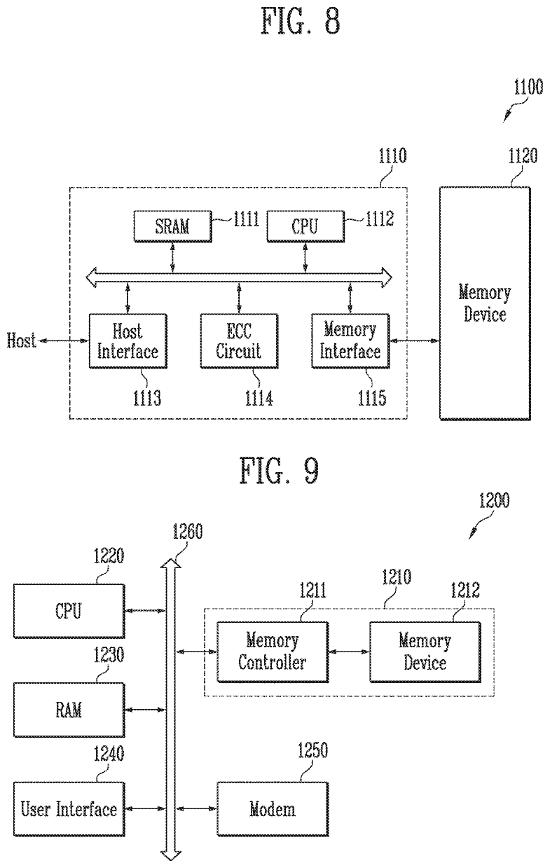

FIG. 8 is a block diagram illustrating a configuration of a memory system 1100 in accordance with an embodiment of the present disclosure.

Referring to FIG. 8, the memory system 1100 includes a memory device 1120 and a memory controller 1110.

The memory device 1120 may include the structure described with reference to FIGS. 1A and 1B, 3, 4, 5A to 5C, or 6. The memory device 1120 may be a multi-chip package configured with a plurality of flash memory chips.

The memory controller 1110 is configured to control the memory device 1120, and may include a Static Random Access Memory (SRAM) 1111, a Central Processing Unit (CPU) 1112, a host interface 1113, an Error Correction Code (ECC) circuit 1114, and a memory interface 1115. The SRAM 1111 is used as an operation memory of the CPU 1112, the CPU 1112 performs overall control operations for data exchange of the memory controller 1110, and the host interface 1113 includes a data exchange protocol for a host connected with the memory system 1100. The ECC circuit 1114 detects and corrects an error included in a data read from the memory device 1120, and the memory interface 1115 interfaces with the memory device 1120. In addition, the memory controller 1110 may further include an ROM for storing code data for interfacing with the host, and the like.

The memory system 1100 configured as described above may be a memory card or a Solid State Disk (SSD), in which the memory device 1120 is combined with the controller 1110. For example, when the memory system 1100 is an SSD, the memory controller 1100 may communicated with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer Small Interface (SCSI) protocol, an Enhanced Small Disk Interface (ESDI) protocol, and an Integrated Drive Electronics (IDE) protocol.

FIG. 9 is a block diagram illustrating a configuration of a computing system 1200 in accordance with an embodiment of the present disclosure.

Referring to FIG. 9, the computing system 1200 may include a CPU 1220, a random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, a Camera Image Processor, a mobile D-RAM, and the like may be further included.

The memory system 1200 may be configured with a memory device 1212 and a memory controller 1211 as described with reference to FIG. 8.

In the semiconductor device in accordance with the present disclosure, a sidewall of a bonding pad includes a curved part. Accordingly, the bonding pad can be formed without any void, and an overlay margin between the bonding pad and a conductor can be secured.

While the present disclosure has been illustrated and described with reference to certain embodiments, it will be understood by those skilled in the art that various changes in form and detail may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or some of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been illustrated and described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A semiconductor device comprising:
a first semiconductor structure including a memory array;
a second semiconductor structure spaced apart from the first semiconductor structure, the second semiconductor structure including a first transistor;
a first insulating layer between the first semiconductor structure and the second semiconductor structure;
a second insulating layer between the second semiconductor structure and the first insulating layer;
a first bonding pad electrically connected to the memory array, the first bonding pad being located in the first insulating layer; and
a second bonding pad electrically connected to the first transistor, the second bonding pad being located in the second insulating layer,
wherein the first bonding pad and the second bonding pad are in contact with each other,
wherein at least one sidewall of sidewalls of the first bonding pad and the second bonding pad includes a curved part.

2. The semiconductor device of claim 1, wherein the at least one sidewall of the first bonding pad and the second bonding pad further includes a flat part.

3. The semiconductor device of claim 2, wherein the flat part includes a first flat part and a second flat part,
wherein the curved part is located between the first and second flat parts.

4. The semiconductor device of claim 1, wherein at least one of the first bonding pad and the second bonding pad includes a first part and a second part each having a flat sidewall,
wherein a width of the first part is greater than a width of the second part.

5. The semiconductor device of claim 4, wherein the at least one of the first bonding pad and the second bonding pad further includes a third part between the first part and the second part,
wherein the third part has a curved sidewall.

6. The semiconductor device of claim 1, wherein the memory array includes:
a stack structure including insulating patterns and conductive patterns; and
a channel structure penetrating the stack structure.

7. The semiconductor device of claim 6, wherein the first semiconductor structure further includes a bit line electrically connected to the channel structure,
wherein the bit line is in contact with the first bonding pad.

8. The semiconductor device of claim 7, wherein a width of a bottom surface of the first bonding pad is equal to a width of the bit line.

9. The semiconductor device of claim 6, wherein the first transistor is a transistor constituting a page buffer.

10. A semiconductor device comprising:
a first semiconductor structure including a stack structure, a channel structure penetrating the stack structure, and a bit line electrically connected to the channel structure;
a second semiconductor structure spaced apart from the first semiconductor structure, the second semiconductor structure including a first transistor;
a first insulating layer between the first semiconductor structure and the second semiconductor structure;
a second insulating layer between the second semiconductor structure and the first insulating layer;
a first bonding pad located in the first insulating layer, the first bonding pad being electrically connected to the channel structure; and
a second bonding pad located in the second insulating layer, the second bonding pad being electrically connected to the first transistor, the second bonding pad being in contact with the first bonding pad,
wherein the first bonding pad includes:
a first part in contact with the second bonding pad;
a second part in contact with the bit line; and
a third part between the first part and the second part,
wherein a sidewall of the third part is curved.

11. The semiconductor device of claim 10, wherein sidewalls of the first part and the second part are flat.

12. The semiconductor device of claim 10, wherein a width of the first part is greater than a width of the second part.

13. The semiconductor device of claim 10, wherein the sidewall of the third part includes a first curved part and a second curved part,
wherein a curvature center of the first curved part is located at the inside of the first bonding pad,
wherein a curvature center of the second curved part is located at the outside of the first bonding pad.

14. The semiconductor device of claim 10, wherein a sidewall of the second bonding pad is curved.
